(19) United States
(12) Patent Application Publication
(10) Pub. No.: US 2021/0319358 A1
(43) Pub. Date: Oct. 14, 2021

(54) LEARNING APPARATUS, COMMUNICATION SYSTEM, AND LEARNING METHOD

(71) Applicant: NEC Corporation, Tokyo (JP)

(72) Inventor: Hideyuki FURUICHI, Tokyo (JP)

(73) Assignee: NEC Corporation, Tokyo (JP)

(21) Appl. No.: 17/223,138

(22) Filed: Apr. 6, 2021

(30) Foreign Application Priority Data
Apr. 8, 2020 (JP) 2020-069482

(51) Int. Cl. G06N 20/00; G06N 5/04; H03M 7/30

(52) U.S. Cl. CPC G06N 20/00; H03M 7/3059; G06N 5/04

(57) ABSTRACT

A learning apparatus includes an acquisition unit configured to acquire communication data transmitted to a network, and a learning unit configured to perform machine learning by using the communication data acquired by the acquisition unit as teacher data. The network includes a communication apparatus and a communication apparatus, and the acquisition unit acquires communication data between the communication apparatuses.

### INCORPORATION BY REFERENCE

This application is based upon and claims the benefit of priority from Japanese patent application No. 2020-069482, filed on Apr. 8, 2020, the disclosure of which is incorporated herein in its entirety by reference.

### TECHNICAL FIELD

The present disclosure relates to a learning apparatus, a communication system, a learning method, and a learning program.

### BACKGROUND ART

In recent years, various types of data that are obtained by network cameras, various types of sensors, computer systems and the like have been used through communication systems including wireless communication systems and wired communication systems. Further, various types of devices have become more sophisticated and their performances have been more improved as exemplified by the improvement in image quality of camera devices. Further, the number of users, and the number of uses/services using such devices have been steadily increasing. Against this background, the amount of distributed data handled by communication systems is explosively increasing, and thus problems such as increased costs, shortages of wireless/wired communication bands, and shortages of system resources are becoming more obvious. Therefore, there is a need for apparatuses and communication methods capable of reducing the amount of communication data without adversely affecting users of services.

For example, a compression technique is used to reduce the amount of communication data. As related art, Japanese Unexamined Patent Application Publications No. 2017-225021 and No. 2012-135588 are known. Japanese Unexamined Patent Application Publications No. 2017-225021 and No. 2012-135588 each disclose a transmission system that transmits video data or image data compressed by a lossless (reversibly) or lossy (irreversibly) compression technique.

### SUMMARY

As described above, a conversion technique such as a compression technique is used, for example, when communication data is transmitted. In the related art, there is a premise that a predetermined lossless compression technique is used in order to ensure that the transmitted data is identical to the original data. However, in the related art, there is a problem that since the related art does not take account of the fact that communication data converted in various methods may be transmitted, it is difficult to cope with arbitrary communication data. In view of the above-described problem, an example object of the present disclosure is to provide a learning apparatus, a communication system, a learning method, and a learning program capable of coping with arbitrary communication data.

In a first example aspect, a learning apparatus includes: an acquisition unit configured to acquire communication data transmitted to a network; and a learning unit configured to perform machine learning by using the acquired communication data as teacher data.

In another example aspect, a communication system includes a first communication apparatus, a second communication apparatus, and a learning apparatus, in which the learning apparatus includes: an acquisition unit configured to acquire communication data transmitted to a network including the first and second communication apparatuses; and a learning unit configured to perform machine learning by using the acquired communication data as teacher data.

In another example aspect, a learning method includes: acquiring communication data transmitted to a network; and performing machine learning by using the acquired communication data as teacher data.

In another example aspect, a learning program is a learning program for causing a computer to: acquire communication data transmitted to a network; and perform machine learning by using the acquired communication data as teacher data.

### BRIEF DESCRIPTION OF DRAWINGS

The above and other aspects, features and advantages of the present disclosure will become more apparent from the following description of certain example embodiments when taken in conjunction with the accompanying drawings, in which:

FIG. 1 is a configuration diagram schematically showing a learning apparatus according to an example embodiment;

FIG. 2 is a configuration diagram schematically showing a communication system according to an example embodiment;

FIG. 3 is a configuration diagram showing an example of a configuration of a communication system according to a first example embodiment;

FIG. 4 is a configuration diagram showing an example of a configuration of a base station according to the first example embodiment;

FIG. 5 is a configuration diagram showing an example of a configuration of a master station of the base station according to the first example embodiment;

FIG. 6 is a configuration diagram showing an example of a functional configuration of the master station of the base station according to the first example embodiment;

FIG. 7 is a diagram showing an example of a configuration of a slave station of the base station according to the first example embodiment;

FIG. 8 is a configuration diagram showing an example of a configuration of a core network according to the first example embodiment;

FIG. 9 is a configuration diagram showing an example of a configuration of a user-plane apparatus of the core network according to the first example embodiment;

FIG. 10 is a sequence diagram showing an example of operations performed by the communication system according to the first example embodiment;

FIG. 11 is a sequence diagram showing an example of operations performed by the communication system according to the first example embodiment;

FIG. 12 is a sequence diagram showing an example of operations performed by the communication system according to the first example embodiment;

FIG. 13 is a configuration diagram showing an example of a configuration of a base station according to a second example embodiment;

FIG. 14 is a configuration diagram showing another example of the configuration of the base station according to the second example embodiment;

FIG. 15 is a diagram showing an example of a configuration of a user-plane apparatus of a core network according to a third example embodiment;

FIG. 16 is a sequence diagram showing an example of operations performed by a communication system according to the third example embodiment;

FIG. 17 is a sequence diagram showing an example of operations performed by the communication system according to the third example embodiment;

FIG. 18 is a configuration diagram showing an example of a configuration of a communication system according to a fourth example embodiment;

FIG. 19 is a sequence diagram showing an example of operations performed by the communication system according to the fourth example embodiment; and

FIG. 20 is a table showing examples of transmitting-side apparatuses and receiving-side apparatuses of a communication system according to other example embodiments.

### EMBODIMENTS

Example embodiments will be described hereinafter with reference to the drawings. For clarifying the explanation, the following descriptions and drawings have been partially omitted and simplified as appropriate. The same elements are denoted by the same reference numerals throughout the drawings, and redundant descriptions thereof are omitted as required. Note that arrows in the configuration diagrams (the block diagrams) are added just for an explanatory purpose, and are not intended to limit the types and the directions of signals.

### (Overview of Example Embodiment)

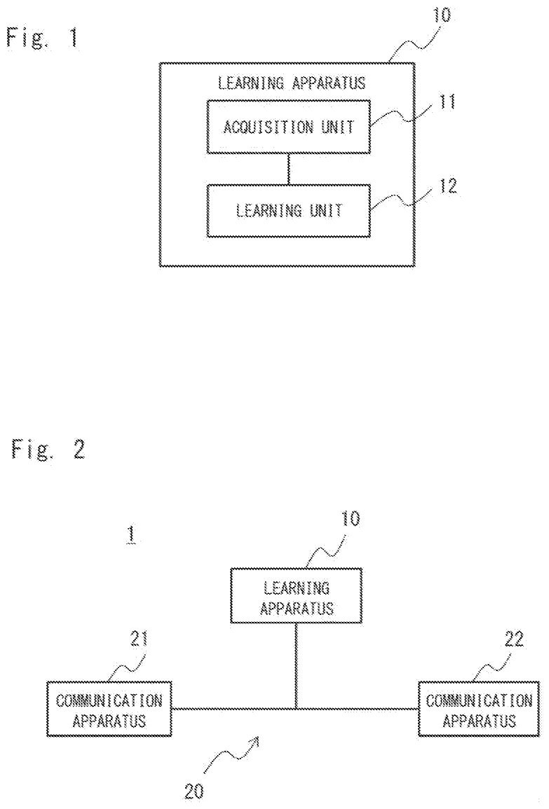

FIG. 1 schematically shows a learning apparatus according to an example embodiment, and FIG. 2 schematically shows a communication system including the learning apparatus according to the example embodiment.

As shown in FIG. 1, the learning apparatus 10 according to the example embodiment includes an acquisition unit 11 and a learning unit 12. The acquisition unit 11 acquires communication data transmitted to a network. The learning unit 12 performs machine learning by using the communication data acquired by the acquisition unit 11 as teacher data. For example, the learning unit 12 machine-learns communication data before it is transmitted to the network and the communication data after it is transmitted to the network.

Further, as shown in FIG. 2, the communication system 1 includes the learning apparatus 10, a communication apparatus (a first communication apparatus) 21, and a communication apparatus (a second communication apparatus) 22. For example, the network 20 includes the communication apparatuses 21 and 22. For example, the acquisition unit 11 acquires communication data transmitted from the communication apparatus 21 to the communication apparatus 22 on the network 20. For example, the learning apparatus 10 is provided in a relay apparatus such as a base station, so that the learning apparatus 10 performs machine learning by using the communication data as teacher data while performing communication.

In the example embodiment, since the learning apparatus performs machine learning by using communication data transmitted to the network as teacher data as described above, it is possible to cope with, for example, arbitrary communication data such as data compressed by a lossy compression technique (hereinafter also referred to as “lossy-compressed data”). Further, by notifying the first communication apparatus (the communication apparatus on the transmitting side, hereinafter also referred to as the “transmitting-side communication apparatus”) and the second communication apparatus (the communication apparatus on the receiving side, hereinafter also referred to as the “receiving-side communication apparatus”) of the result of the machine learning, they can perform communication by using an appropriate method according to the result of the learning. For example, by notifying the communication apparatuses of a variable(s) and/or a program(s) of the compression method and/or the inference method, it is possible to appropriately perform, on the receiving side, decompression, restoration, interpolation, and/or the like for data which has been lossy-compressed and/or thinned-out on the transmitting side.

In the case of the communication apparatuses and the communication methods in the related art, it is necessary to compress communication data by a lossless compression technique (hereinafter also expressed as “to lossless-compress communication data”) when the amount of communication data needs to be reduced. However, it is impossible to sufficiently reduce the amount of communication data by using lossless compression as compared to when lossy compression is used. However, when the lossy compression is used, for example, the image quality of image data or video data (i.e., moving-image data) is deteriorated, so that it is difficult for a user or a system that handles the transmitted data to identify an object to be checked from the image or the moving image.

Further, even if machine learning is simply employed in a related system or a web service, it is impossible to reduce the amount of communication data in the network used by the system. In this case, it is necessary to create a model by preparing learning data and teacher data in advance. Therefore, it is impossible to cope with the current business environment in which user requirements and system requirements widely change and are uncertain and complicated, and their ambiguousness needs to be allowed. In particular, it is difficult to simply use a machine learning method in the communication network used by the system.

Therefore, in example embodiments, it is made possible to appropriately cope with various communication data by machine-learning communication data transmitted to the network and thereby inferring original data (i.e., data that has not been converted yet (e.g., has not been compressed yet)) from data that has been converted by an arbitrary method.

### First Example Embodiment

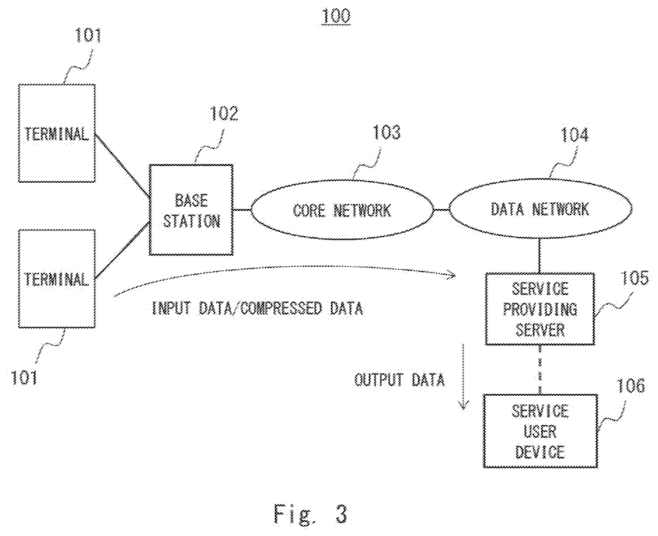

A first example embodiment will be described hereinafter with reference to the drawings. FIG. 3 shows an example of a configuration of a communication system according to this example embodiment. As shown in FIG. 3, a communication system 100 according to this example embodiment includes a plurality of terminals 101, a base station 102, a core network 103, a data network 104, a service providing server 105, and a service user device (apparatus) 106.

In the communication system 100, the terminal 101 (the transmitting side) transmits input data, and the service providing server 105 (the receiving side) provides output data obtained by processing the input data to the service user device 106. Further, the terminal 101 compresses the input data by a lossy compression technique (hereinafter also expressed as “lossy-compresses the input data”) and transmits the lossy-compressed data, and the service providing server 105 performs decompression, restoration, and the like for the lossy-compressed data, and provides output data obtained based on the decompression, the restoration, and the like to the service user device 106. The compression method and the decompression/restoration method (the inference method) are determined based on the communication data and/or information provided to a user of a service. In this example embodiment, the compression method and the inference method are determined by performing machine learning in the base station 102.

The terminal (the first communication apparatus) 101 is an input apparatus that generates (acquires) input data. For example, the terminal 101 generates input data from data acquired by an image-pickup device, a sensor device, or the like as described later. The plurality of terminals 101 are, for example, radio communication terminals, and are wirelessly connected to the base station 102 so as to be able to communicate with the base station 102. The terminal 101 transmits input data to the service providing server 105 through the base station 102, the core network 103, and the data network 104. Further, the terminal 101 also serves as a compression apparatus that compresses (lossy-compresses) input data according to a compression method notified from the base station 102 (i.e., a compression method of which the terminal 101 is notified by the base station 102).

The base station 102 is a radio base station capable of accommodating the plurality of terminals 101. The base station 102 is connected to the plurality of terminals 101 and the core network 103 so as to be able to communicate with them, and serves as a relay apparatus that relays communication between the plurality of terminals 101 and the core network 103. In this example embodiment, the base station 102 also serves as a learning apparatus that machine-learns communication data. The base station 102 machine-learns communication data before it is transmitted to the network and the communication data after it is transmitted to the network by using the communication data transmitted to the network as teacher data. In this example, the base station 102 performs machine learning by using input data and output data as teacher data. The base station 102 notifies the terminal 101 of a compression method for compressing the input data according to the result of the machine learning, and notifies the service providing server 105 of an inference method for inferring the input data from the compressed data.

The core network 103 is a network that serves as the backbone of the communication system 100. The core network 103 is connected to the base station 102 and the data network 104 so as to be able to communicate with them, and relays communication between the base station 102 and the data network 104.

The data network 104 is a network for relaying data of the service providing server 105 (which may include the service user device 106). The data network 104 may be, for example, a dedicated network or an intranet for an enterprise or a business owner, the Internet, or the like. The data network 104 is connected to the core network 103 and the service providing server 105 so as to be able to communicate with them, and relays communication between the core network 103 and the service providing server 105.

The service providing server (the second communication apparatus) 105 is a server that provides a service (data) to the service user device 106. The service providing server 105 is connected to a data network 104 and a service user device 106 so as to be able to communicate with them, receives input data from the terminal 101 through the data network 104, and transmits output data obtained based on the input data to the service user device 106. The service providing server 105 performs an output-data generating process (has an output-data generating function) for generating output data from input data. Further, the service providing server 105 also serves as an inference apparatus (a restoration apparatus) that infers input data from compressed data according to the inference method notified from the base station 102.

The service user device 106 is a device used by a user of the service. The service user device 106 is connected to a service providing server 105 so as to be able to communicate with the service providing server 105, and receives the output data from the service providing server 105. Note the only requirement is that the service providing server 105 and the service user device 106 should be connected to each other so that output data can be transmitted therebetween, and there is no restriction on the connection method therebetween. For example, they may be connected to each other through the data network 104, or they may be connected to each other through other networks.

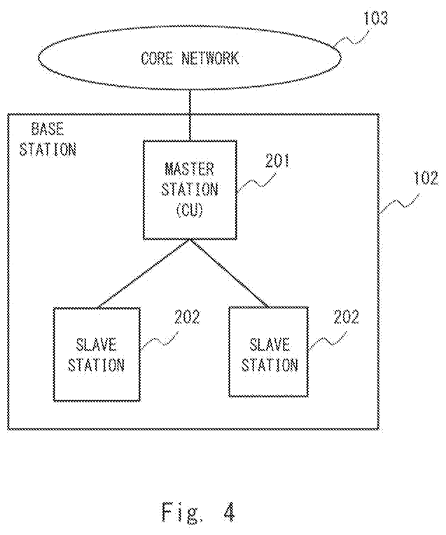

FIG. 4 shows an example of a configuration of a base station according to this example embodiment. As shown in FIG. 4, the base station 102 according to this example embodiment includes a master station 201 and one or a plurality of slave stations 202. The master station 201 accommodates the one or plurality of slave stations 202 and serves as a central unit (CU: Central Unit) connected to the core network 103. Each of the slave stations 202 transmits/receives data to/from a plurality of terminals 101, and transfers the transmitted/received data to the master station 201.

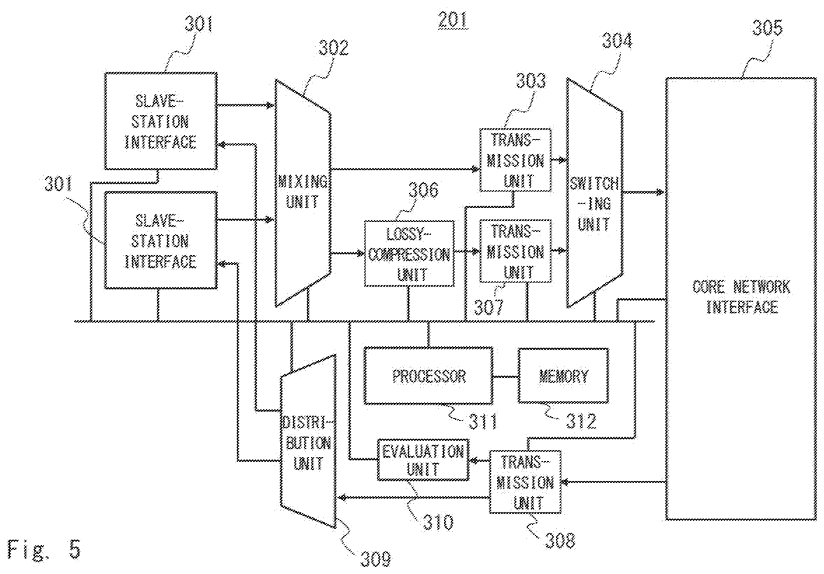

FIG. 5 shows an example of a detailed configuration of a master station provided in a base station according to this example embodiment. As shown in FIG. 5, the master station 201 according to this example embodiment includes a plurality of slave-station interfaces 301, a mixing unit 302, a lossy-compression unit 306, a transmission unit 303, a transmission unit 307, a switching unit 304, a core network interface 305, a transmission unit 308, an evaluation unit 310, a distribution unit 309, a processor 311, and a memory 312.

The processor 311 and the memory 312 constitute a control unit that controls each interface and each unit (each function) of the master station 201. The processor 311 is connected to each interface and each unit. The memory 312 stores software (a program(s)), and as the processor 311 executes the software stored in the memory 312 (hereinafter referred to as the “software processing”), the function for controlling each interface and each unit is implemented.

Each of the slave-station interfaces 301 is an interface connected to a respective one of the slave stations 202, and receives and outputs data received from the terminal 101 and data to be transmitted to the terminal 101 from and to the slave station 202. The mixing unit (the mixing function) 302 multiplexes (mixes) the data (communication) that the plurality of slave-station interfaces 301 have received from the slave stations 202, and outputs the multiplexed data. The multiplexing method performed by the mixing unit 302 is controlled by software processing. The transmission unit (the transmission function) 303 transmits the data output from the mixing unit 302 to the switching unit 304.

The lossy-compression unit (the lossy-compression function) 306 lossy-compresses the data output from the mixing unit 302 and outputs the lossy-compressed data. The transmission unit (the transmission function) 307 transmits the data lossy-compressed by the lossy-compression unit 306 to the switching unit 304.

The switching unit (the switching function) 304 switches (i.e., selects) the transmission method for data transmitted from the transmission unit 303 and data transmitted from the transmission unit 307, and transmits the data to the core network interface 305 by using the selected method. The switching unit 304 determines (identifies) whether or not the transmitted data (communication) is data from a terminal 101 for a specific application (hereinafter also referred to as an “application-specific terminal 101”) and determines whether or not the transmitted data is data to be transmitted to a server for a specific application (hereinafter also referred to an “application-specific server”). Further, the switching unit 304 determines (identifies) whether the data to be transmitted is compressed data or uncompressed data.

The switching unit 304 selects (switches) whether to transmit the data of the transmission unit 303 (i.e., the uncompressed data), transmit the data of the transmission unit 307 (i.e., the compressed data), multiplex both of them and transmit the multiplexed data, or transmit neither of them. The switching unit 304 switches (i.e., selects) the destination of the transmission of the communication data. The switching unit 304 selects whether to change the destination of the communication data to a local server 602 (described later), change it to the service providing server 105, or transmit the communication data without changing the destination. The switching unit 304 can add tag information indicating whether the transmitted data is uncompressed data or compressed data. Note that the switching unit 304 may add no tag information. The operation of the switching unit 304 is controlled by software processing.

The core network interface 305 is an interface connected to the core network 103, and receives and outputs data to be transmitted to the service providing server 105 and data received from the core network 103 from and to the core network 103. The transmission unit (the transmission function) 308 outputs the data that the core network interface 305 has received from the core network 103 to the evaluation unit 310 and the distribution unit 309. Then evaluation unit (the evaluating function) 310 evaluates the data transmitted from the transmission unit 308.

The distribution unit (the distributing function) 309 distributes the data transmitted from the transmission unit 308 to the slave-station interfaces 301. The distribution unit 309 distributes the multiplexed communication data with the plurality of slave stations 202 to the respective slave stations 202. The operation of the distribution unit 309 is controlled by software processing.

Uplink communication data from the slave stations 202 is transmitted to the core network 103 through the respective slave-station interfaces 301, the mixing unit 302, the transmission unit 303, the switching unit 304, and the core network interface 305. The uplink communication data is also transmitted to the core network 103 through the slave-station interfaces 301, the mixing unit 302, the lossy-compression unit 306, the transmission unit 307, the switching unit 304, and the core network interface 305. Downlink communication from the core network 103 is transmitted to the slave stations 202 through the core network interface 305, the transmission unit 308, the distribution unit 309, and the slave-station interfaces 301. A part of the downlink communication data is also transmitted to the evaluation unit 310 from the transmission unit 308.

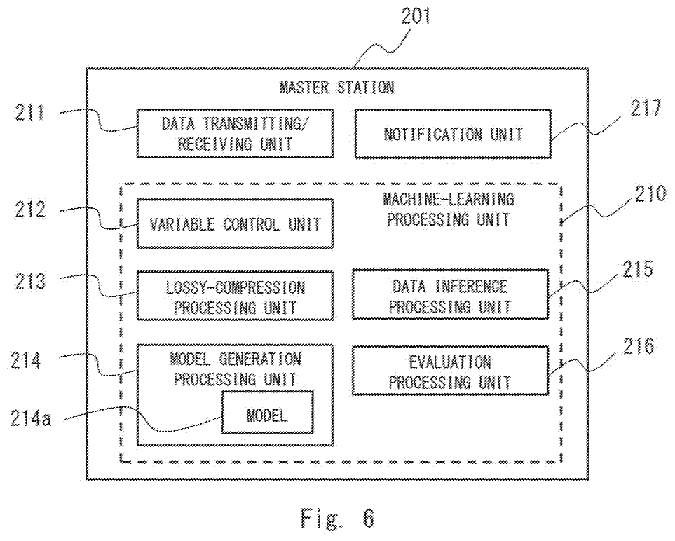

FIG. 6 shows an example of a configuration of a process (a function) implemented by software processing including hardware processing performed by the master station 201. As shown in FIG. 6, the master station 201 includes a data transmitting/receiving unit 211, a machine learning processing unit 210, and a notification unit 217. Further, the machine learning processing unit 210 includes a variable control unit 212, a lossy-compression processing unit 213, a model generation processing unit 214, a data inference processing unit 215, and an evaluation processing unit 216.

In a machine-learning process according to this example embodiment, machine learning is performed by identifying communication data transmitted from an application-specific terminal, identifying communication data transmitted to an application-specific server, and using these communication data as teacher data. In particular, output data that is obtained by processing input data (unprocessed data) by using a service providing server is used as teacher data.

The data transmitting/receiving unit 211 transmits/receives data between the terminal 101 and the service providing server 105, and acquires data necessary for the machine learning. For example, the data transmitting/receiving unit 211 acquires input data transmitted from the terminal 101 to the service providing server 105 (data transmitted from the application-specific terminal to the application-specific server), and acquires output data transmitted from the service providing server 105 (data transmitted from the application-specific server to the application-specific device or the base station). Further, the data transmitting/receiving unit 211 transmits inferred data of the input data to the local server 602 and receives inferred data of the output data from the local server 602. For example, the data transmitting/receiving unit 211 is implemented by software processing, the slave-station interfaces 301, the core network interface 305, the transmission unit 303, the transmission unit 307, and the transmission unit 308.

The variable control unit (the setting unit) 212 controls a variable(s) (a parameter(s)) necessary for the machine learning. For example, the variable control unit 212 controls a variable (a compression method or a conversion method) for lossy compression performed in the lossy-compression processing unit 213, and controls a variable (an inference method) for the generation of a model performed in the model generation processing unit 214. The variable control unit 212 sets these variables and adjusts the set variables according to the evaluation result. For example, the variable control unit 212 is implemented by software processing.

The lossy-compression processing unit (the conversion unit) 213 lossy-compresses (converts) data by a compression method (a conversion method) determined according to the setting of the variable. For example, the lossy-compression processing unit 213 is implemented by software processing and the lossy-compression unit 306.

The model generation processing unit (the generation unit) 214 creates a model for generating (inferring) the original data from the lossy-compressed data by using the inference method determined according to the setting of the variable. The model is a learning model defined in the field of machine learning, and makes it possible to predict data corresponding to the learning result based on supplied data. For example, the model generation processing unit 214 is implemented by software processing. The model generation processing unit 214 stores a generated model 214a in the memory 312, and updates the model 214a according to the machine learning.

The data inference processing unit (the inference unit) 215 infers the original data (the input data that has not been converted yet) from the lossy-compressed data (the converted input data) by using the generated model 214a. For example, the data inference processing unit 215 is implemented by software processing.

The evaluation processing unit (the evaluation unit) 216 evaluates the generated model 214a. The evaluation processing unit 216 evaluates the model 214a by comparing data that is inferred based on the model 214a with actual data. For example, the evaluation processing unit 216 evaluates the model 214a by comparing a result of processing in which data that is inferred by using the model 214a is processed by the local server 602 (a result of processing of output data based on the inferred input data, i.e., a result of processing of the processed data) with a result of processing of the service providing server 105 (a result of processing of output data acquired from the service providing server 105, i.e., a result of processing of the unprocessed data). For example, the evaluation processing unit 216 is implemented by software processing and the evaluation unit 310. Note that the master station 201 may not include the evaluation unit 310, and the evaluation processing unit 216 may be implemented by software processing alone.

The notification unit 217 notifies the terminal 101 of the method for compressing input data (information about the adjustment and the learned conversion method) and notifies the service providing server 105 of the method for inferring the input data (information about the adjustment and the learned inference method) according to the result of the machine learning (i.e., according to the model 214a). For example, the notification unit 217 is implemented by software processing, the slave-station interfaces 301, and the core network interface 305.

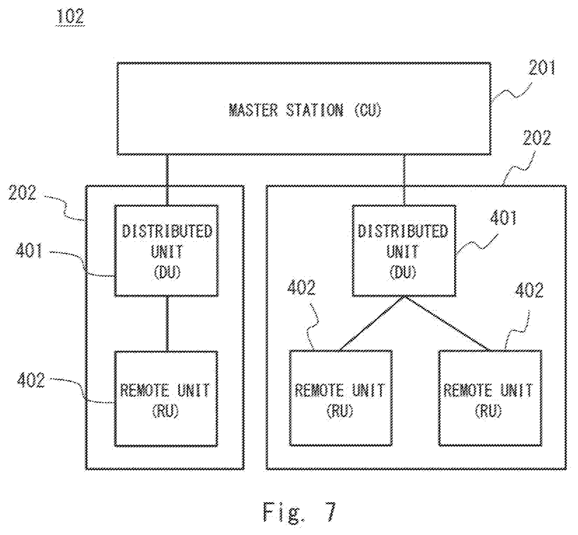

FIG. 7 shows an example of a detailed configuration of a slave station provided in a base station according to this example embodiment. As shown in FIG. 7, the slave station 202 according to this example embodiment includes a distributed unit (DU: Distributed Unit) 401 and one or a plurality of remote units (RU: Remote Unit) 402. The distributed unit 401 is connected to the master station 201 and also connected to the one or plurality of remote units 402. Each of the remote units 402 is connected to a plurality of terminals 101, and performs radio communication with the terminals 101 and transmits/receives data to/from them.

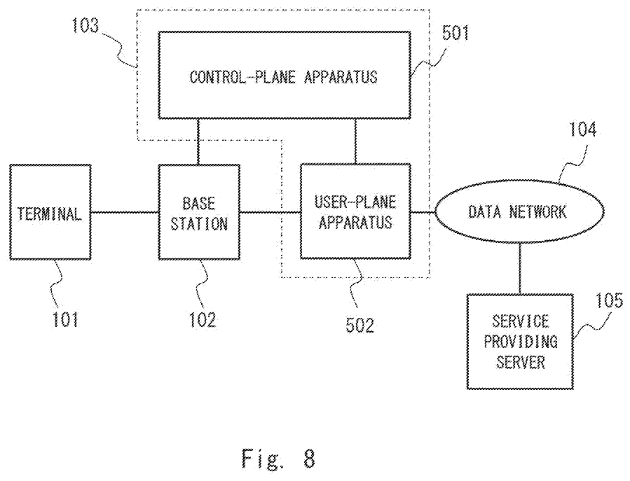

FIG. 8 shows an example of a detailed configuration of a core network according to this example embodiment. As shown in FIG. 8, the core network 103 according to this example embodiment includes a control-plane apparatus 501 and a user-plane apparatus 502. The control plane (C-Plane: Control Plane) is, in the core network(s), a network for transmitting a control signal, and a user plane (U-Plane: User Plane) is a network for transmitting user data (communication data).

The control-plane apparatus 501 is a control-signal relay unit of the core network 103, and relays a control signal between the base station 102 and the data network 104. The control-plane apparatus 501 is connected to the base station 102 and the user-plane apparatus 502, and also connected to the service providing server 105 through the user-plane apparatus 502 and the data network 104.

The user-plane apparatus 502 is a user-data relay unit of the core network 103, and relays user data between the base station 102 and the data network 104. The user-plane apparatus 502 is connected to the base station 102, the control-plane apparatus 501, and the data network 104, and also connected to the service providing server 105 through the data network 104.

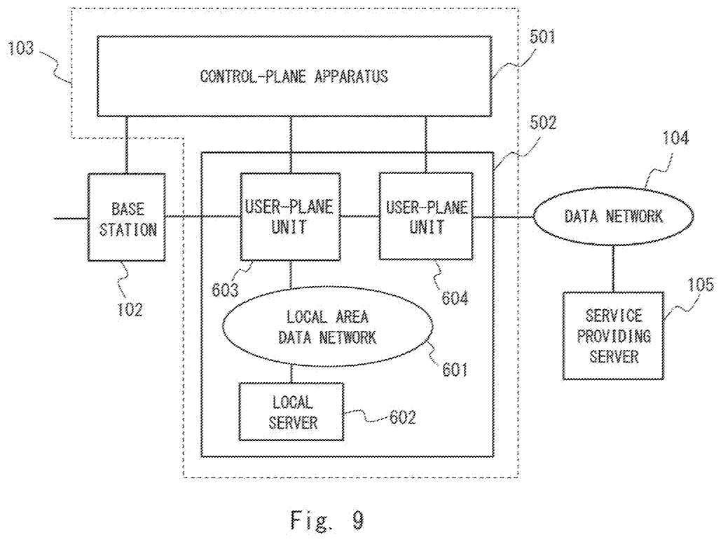

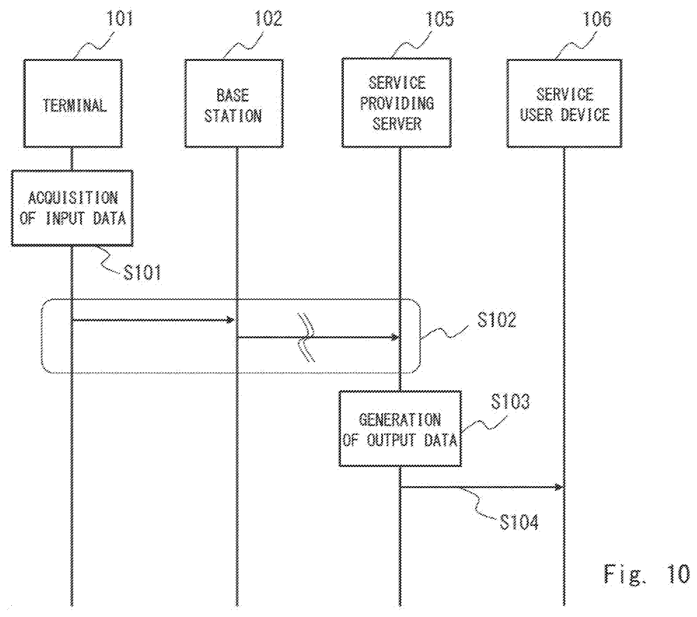

FIG. 9 shows an example of a detailed configuration of a user-plane apparatus according to this example embodiment. As shown in FIG. 9, the user-plane apparatus 502 according to this example embodiment includes a plurality of user-plane units (U-Plane functions) 603 and 604, a local area data network 601, and a local server 602.

Each of the user-plane units 603 and 604 relays user data between base station 102 and data network 104. Further, the user-plane unit 603 relays user data from/to the local server 602. The user-plane unit 603 is connected to the base station 102, the control-plane apparatus 501, the user-plane unit 604, and the local area data network 601, and also connected to the local server 602 through the local area data network 601. The user-plane unit 604 is connected to the user-plane unit 603, the control-plane apparatus 501, and the data network 104.

The local area data network 601 is connected to the user-plane unit 603 and the local server 602, and relays user data. The local server 602 performs machine learning in cooperation with the base station 102 (the master station 201). Specifically, the local server 602 generates output data based on input data that the base station 102 has inferred by using the model. The local server (the output-data generation unit) 602 generates the output data from the input data by using the same method as that used by the service providing server 105 (the output-data generation method).

### <Operation in First Example Embodiment>

Next, operations performed by the communication system according to this example embodiment will be described. FIG. 10 shows a data transmitting/receiving operation performed in the communication system 100 according to this example embodiment, in which data is transmitted/received from the terminal 101 to the service providing server 105 (the service user device 106).

As shown in FIG. 10, in the data transmitting/receiving operation, firstly the terminal 101 acquires (generates) input data (S101). The input data is data that is processed by the service providing server 105 and provided to the service user device 106. For example, the terminal 101 uses data acquired from various types of devices as input data. The various types of devices may be connected to the terminal 101 or disposed inside the terminal 101.

Examples of the various types of devices include an image-pickup device, a sensor device, a microphone device, a reading device, a user interface, and a biometric device. In the case of the image-pickup device, the input data is data of a moving image or a still image taken by the image-pickup device. In the case of the sensor device or the measuring device, the input data is measured data. For example, the input data is a temperature, a humidity, an altitude, a latitude and a longitude, an acceleration, an inclination, a moving distance, a heart rate, biological data, a flow rate, a pressure, an electric current value, a voltage value, an electromagnetic value, an amount of light, an amount of radiation, a sound level, an acidity, or scientific/chemical data. In the case of the microphone device, the input data is input voice data. In the case of the reading device, the input data is acquired reading data. For example, the input data is bar-code data, QR code (Registered Trademark) data, RFID data, or magnetic data. In the case of the user interface, the input data is input operation data input by a user. For example, the input data is text data entered through a keyboard or image data input through a pen-and-tablet device. In the case of the biometric device, the input data is biometric data input by a user. For example, the input data is a fingerprint, a voiceprint, an iris, or a vein pattern.

Further, the input data is not limited to data obtained by various types of devices, and may be data generated by other types of hardware or software processing. The input data may be generated by hardware located outside the terminal 101 or software processing performed by an entity other than the terminal 101, or may be generated by hardware disposed inside the terminal 101 or software processing performed by the terminal 101. For example, the format of the input data is text data, binary data, numerical data, or the like.

Next, the input data is transmitted and received between the terminal 101 and the service providing server 105 (S102). When the terminal 101 transmits generated input data to the service providing server 105, the input data is transferred to the base station 102, the user-plane apparatus 502 of the core network 103, and the data network 104 in this order, and received by the service providing server 105.

Next, the service providing server 105 generates output data based on the input data (S103). The service providing server 105 generates the output data based on the input data by performing software processing for the received input data. For example, the output data is data or information of a service requested by a user of the service, data or information belonging to a service requested by a user of the service, or data or information for controlling the service user device 106. For example, when the service providing server 105 receives data of a moving image or a still image from the terminal 101, it generates output data by converting the received data into data in a predetermined format for the service user device 106. The output-data generating process may be determined for each service or for each user (each device) of the service, or may be determined for each terminal or for input data (for each format).

Next, the service user device 106 acquires the output data from the service providing server 105 (S104). For example, the service user device 106 transmits a GET (request) of a HTTP method to the service providing server 105 through a REST API (Representational State Transfer Application Programming Interface), and acquires output data from the service providing server 105. The service user device 106 may acquire data from the service providing server 105 through other APIs, or the service providing server 105 may send output data to the service user device 106.

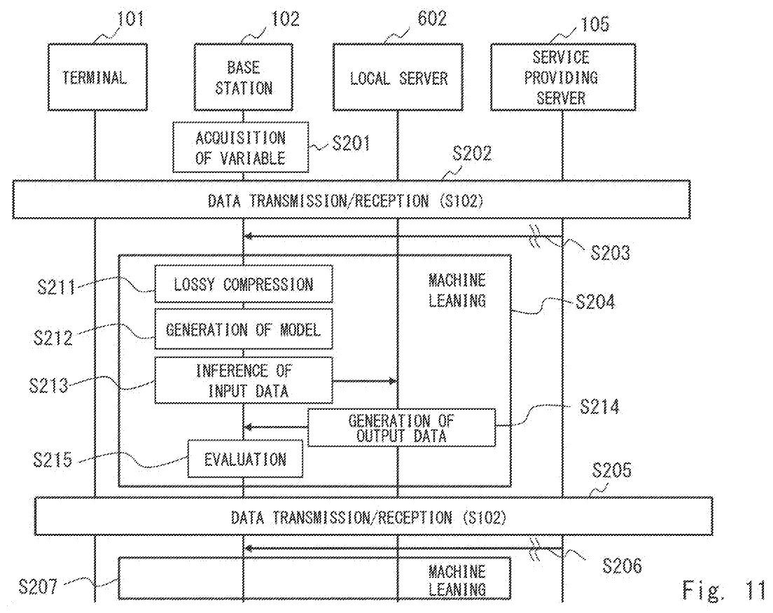

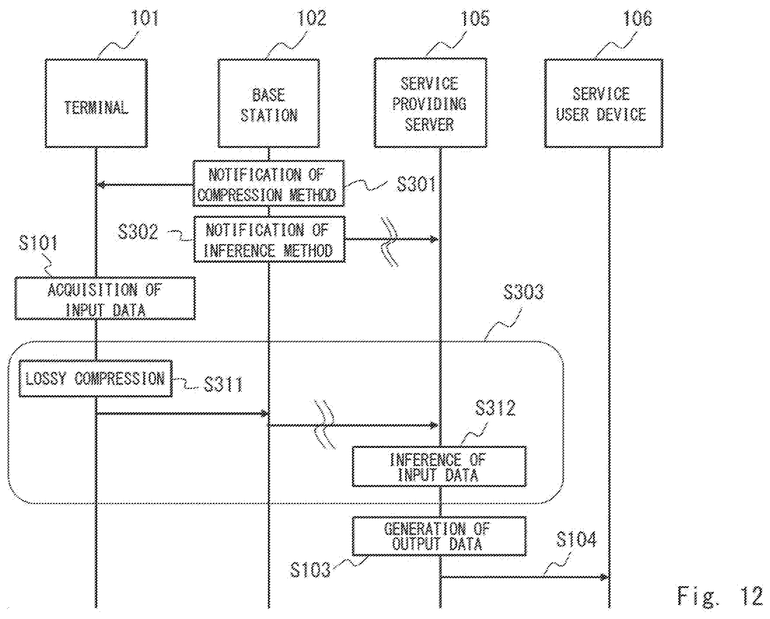

FIG. 11 shows a learning operation performed in the communication system 100 according to this example embodiment. In this example embodiment, while the communication (the data transmission/reception) described above with reference to FIG. 10 is being performed, its communication data is machine-learned.

As shown in FIG. 11, firstly, the base station 102 (the variable control unit 212) acquires several variables (S201). Some of the acquired variables are variables necessary for the machine-learning process and include parameters for lossy compression, parameters for a learning model, and the like. Variables that are stored in advance in a memory provided inside the base station 102 may be acquired, or variables may be acquired (received) from an external apparatus.

Next, similarly to the step S102 in FIG. 10, data is transmitted and received between the terminal 101 and the service providing server 105 (S202). That is, input data is transmitted from the terminal 101 to the service providing server 105, and the base station 102 acquires the input data transmitted from the terminal 101.

Next, the base station 102 acquires output data from the service providing server 105 (S203). Similarly to the step S103 in FIG. 10, the service providing server 105 generates output data from the input data, and similarly to the step S104 in FIG. 10, the base station 102 acquires the output data from the service providing server 105.

Next, the base station 102 performs machine learning in cooperation with the local server 602 of the user-plane apparatus 502 (S204). The machine learning process (S204) includes a lossy-compression process (S211), a model generation process (S212), an input-data inference process (S213), an output-data generation process (S214), and an evaluation process (S215).

In the machine-learning process, firstly, the base station 102 (the lossy-compression processing unit 213) lossy-compresses the input data acquired from the terminal 101 (S211). The lossy-compression process is, for example, a process for thinning out input data, a quantization process, a filtering process, a convolution process, a pooling process, or the like, and may include only one process or a plurality of processes. The process for thinning out input data includes, for example, thinning out data divided according to the time (time-series data), thinning out data divided according to the space, thinning out data divided according to the frequency, or thinning out data that has been subjected to quadrature encoding/vector resolution. The convolution process is also referred to as convolution calculation, and is a process used in, for example, a discrete Fourier transform. The pooling process is a process used for image processing or the like, and is, for example, a process for obtaining an average value or a maximum value within a window.

The base station 102 compresses the input data by a compression method that is determined according to the acquired variable(s). That is, in the lossy-compression process, details of the compression method such as information as to what kind of a compression method should be used, information as to how much degree the data should be compressed, and information about the maximum amount and the minimum amount of the compressed data are controlled by using the several variables obtained in the step S201.

Next, the base station 102 (the model generation processing unit 214) generates a model 214a for inferring data corresponding to the input data from the lossy-compressed data (S212). The model generation process includes, for example, a process for generating a neural network, weighting of nodes in the neural network, parameter setting, and the like. The base station 102 generates the model 214a by using the generation method determined according to the acquired variable(s). That is, in the model generation process, details of the method for generating a model, such as information as to what kind of a model should be generated, information as to what values the input and output values of the model should be set to, information as to the number of layers and the number of nodes in the model, and information as to how much weights should be set, are controlled by the several variables obtained in the step S201. The generated model 214a is stored in a memory and updated in the next machine learning. The model generation process is also considered to be an update process for updating the model every time the machine learning is repeated.

Next, the base station 102 (the data inference processing unit 215) infers (generates) data corresponding to the input data from the lossy-compressed data by using the generated model 214a (S213). The base station 102 inputs the lossy-compressed data generated in the step S211 into the model 214a, infers the input data, and outputs (transmits) the inferred input data to the local server 602.

Next, the local server 602 generates output data from the input data (S214). The local server 602 performs software processing that is the same as or similar to the process for obtaining output data performed by the service providing server 105 (S103). The local server 602 generates the output data from the input data inferred by the base station 102 through a process similar to that performed by the service providing server 105. The local server 602 generates inferred data of the output data from the inferred data of the input data, and provides (transmits) the generated inferred data of the output data to the base station 102.

Next, the base station 102 (the evaluation processing unit 216) evaluates the output data (the model) (S215). The base station 102 compares the output data obtained from the service providing server 105 in the step S203 with the inferred data of the output data obtained from the local server 602 in the step S214, and outputs an evaluation value indicating the result of the evaluation. It is indicated that the smaller the evaluation value is, the smaller the difference between the actual output data and the inferred data of the output data is. For example, the evaluation value is stored in the memory and used in the next machine-learning process. Note that, in the evaluation process, the data that is output as the evaluation value is not limited to the evaluation value itself. That is, some variables (variables corresponding to the evaluation result) as well as the evaluation value may be output. In the following description, the meaning of the term “evaluation value” includes not only the evaluation value itself but also some variables as well as the evaluation value.

Further, similarly to the steps S202 to S204, data is transmitted and received between the terminal 101 and the service providing server 105 (S205), and the base station 102 acquires output data from the service providing server 105 (S206) and performs machine learning (S207).

The difference between the machine-learning process in the step S207 and the machine-learning process in the step S204 will be described. A first difference is a difference of data that is machine-learned. That is, in the step S204, the machine learning is performed by using the input data obtained in the step S202 and the output data obtained in the step S203. In contrast, in the step S207, the machine learning is performed by using the input data obtained in the step S205 and the output data obtained in the step S206 in addition to the aforementioned input data and the output data.

A second difference is a difference of values that are used to control the machine learning. That is, in the step S204, the control of the lossy compression in the step S211 and the control of the generation of a model in the step S212 are performed by using the variables obtained in the step S201. In contrast, in the step S207, the processes in the steps S211 and S212 are control by using the variables obtained in the step S201 and the evaluation value output in the step S215. That is, the variables for the lossy-compression process is adjusted according to the evaluation result obtained in the step S215, and the variables for the model generation process are adjusted according to the evaluation result obtained in the step S215. Both the lossy-compression process (the compression method) and the model generation process (the inference method) may be adjusted according to the evaluation value, or only one of them may be adjusted according to the evaluation value. For example, the compression ratio for the lossy compression may be changed according to the evaluation value, and/or the weighting in the model may be changed according to the evaluation value.

In this example embodiment, the machine learning in the step S207 is repeated until the evaluation value becomes smaller than a certain value (a constant, or one of several variables in S201). Every time communication from the terminal 101 to the service providing server 105 is performed in the step S205, the processes in the steps S206 and S207 are performed, so that it is possible to increase the data used for the machine learning and thereby improve the accuracy of the model without interrupting the communication.

The data used for the machine learning is the input data from the terminal 101, the input data lossy-compressed by the base station 102, the output data obtained by processing the input data by using the service providing server 105, and the output data obtained by processing the input data lossy-compressed by the local server 602. In this example embodiment, the steps S206 and S207 are performed (i.e., repeated) until the number of repetitions exceeds a certain value (a constant, or one of the several variables in S201). Then, when the number of repetitions exceeds the certain value, the execution of the steps S206 and S207 is finished.

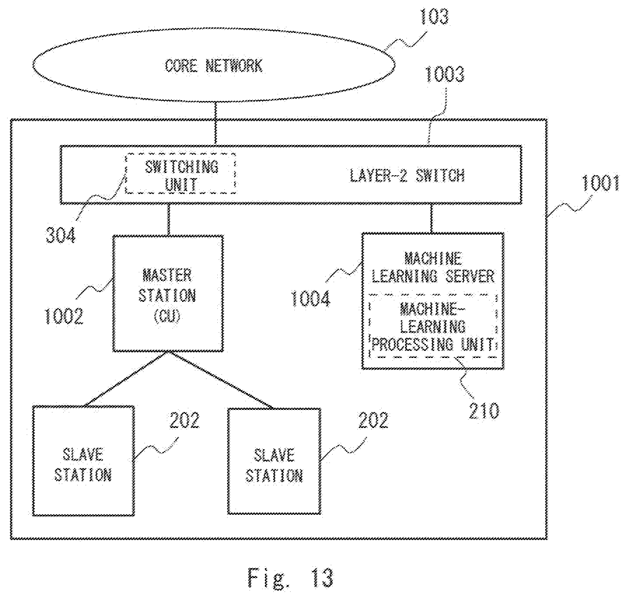

FIG. 12 shows operations that are performed subsequent to the learning operation shown in FIG. 11, and shows compression and inference operations performed on the transmitting side and the receiving side, respectively, according to this example embodiment. For example, when the machine-learning process shown in FIG. 11 is finished, it is possible to switch (i.e., change) the compression and inference method while performing communication.

As shown in FIG. 12, firstly, the base station 102 notifies the terminal 101 of a method for lossy-compressing input data (S301). The terminal 101 has a function that is the same as or similar to that of the lossy-compression unit 306 of the base station 102. Therefore, by having the base station 102 notify the terminal 101 of the several variables (parameters for the conversion) used in the control performed by the lossy-compression unit 306, and having the terminal 101 use these variables, it is possible to perform lossy compression by using the same method as that used by the base station 102.

Further, the terminal 101 may implement the function that is the same as or similar to that of the lossy-compression unit 306 by software processing. For example, the base station 102 may transmit a program for implementing a function (software for performing the conversion) that is the same as or similar to that of the lossy-compression unit 306 to the terminal 101, and the terminal 101 may perform lossy compression by the same method as that performed by the base station 102 by executing the transmitted program.

Next, the base station 102 notifies the service providing server 105 of a method for inferring input data (S302). Similarly to the data inference processing unit 215 (and the model generation processing unit 214) of the base station 102, the service providing server 105 has a function of inferring data using a learned model. For example, similar to the base station 102, this function is implemented by software processing. Therefore, the base station 102 transmits the model 214a that has been generated and learned in the step S212 in FIG. 11, and the service providing server 105 infers the input data by using this model, so that the service providing server 105 can infer the input data by the same method as that performed by the base station 102. A variable(s) (a parameter(s)) for the inference method (the model) may be transmitted from the base station 102, or a program for performing the inference method may be transmitted from the base station 102. In such a case, the service providing server 105 may generate the model by using the received variable(s) or the program.

Note that, in this example, the service providing server 105 is notified of the inference method (S302) after the terminal 101 is notified of the compression method (S301). However, the terminal 101 may be notified of the compression method (S301) after the service providing server 105 is notified of the inference method (S302).

After that, an operation for transmitting/receiving data similar to the operation shown in FIG. 10 is performed by using the notified (i.e., indicated) compression method and inference method. That is, similarly to the step S101 in FIG. 10, when the terminal 101 acquires the input data, the data is transmitted/received in the step S303 instead of being transmitted/received in the step S102 shown in FIG. 10.

In the data transmission/reception process in the step S303, the terminal 101 lossy-compresses the input data by the compression method notified (i.e., indicated) in the step S301 (S311), and transmits the lossy-compressed data (the converted input data) to the service providing server 105. The service providing server 105 receives the lossy-compressed data through the base station 102 and the like, and infers the input data (the input data that has not been converted yet) from the received data (i.e., performs decompression, restoration, and the like for the lossy-compressed data) by using the inference method notified (i.e., indicated) in the step S302 (S312).

Next, similarly to FIG. 10 (i.e., without changing the procedure), the service providing server 105 generates output data from the input data inferred in the step S312 (S103). Further, similarly to FIG. 10 (i.e., without changing the procedure), the service user device 106 acquires output data from the service providing server 105 (S104).

### <Effect of First Example Embodiment>

Advantageous effects of this example embodiment will be described. A first advantageous effect is that the amount of communication data in the network used by the system or the server can be reduced. The reason for this advantageous effect is that, according to the method in accordance with this example embodiment, the transmitting side lossy-compresses input data and transmits the lossy-compressed input data, and the receiving side infers the input data (i.e., performs decompression, restoration, and the like for the lossy-compressed data).

A second advantageous effect is that the amount of compressed communication data can be controlled (i.e., adjusted) to an arbitrary amount. The reason for this advantageous effect is that whether data should be compressed by a lossy-compression method and the lossy compression method itself are controlled by using variables. This is because while the lossless-compression method cannot reduce information (the amount of information), the lossy-compression method can reduce information (the amount of information).

A third advantageous effect is that the amount of communication data can be reduced without impairing the usability for users. The reason for this advantageous effect is that output data of the server that is output when communication data is compressed, i.e., information that a user can actually use is used for the machine learning. Since the information that a user can actually use is used, it is possible to evaluate the fact that the usability for the user is not impaired. In this example embodiment, a model for machine learning is evaluated based on the result of the processing of data. That is, a model for machine learning is evaluated based on the difference between the result of the processing of unprocessed data (the original data) and the result of the processing of processed data (data that is obtained by lossy-compressing input data, and performing decompression, restoration, interpolation, and the like for the lossy-compressed data).

A fourth advantageous effect is that even if the terminal or the server of the system that provides a service, or software processing for them is changed, there is no need to change the communication apparatus and communication method, and there is no adverse effect on users of the service. A first reason for this advantageous effect is that the communication apparatus and the communication method according to this example embodiment have a function/method for machine learning in the base station or in the core network. A second reason for the advantageous effect is that the local server in this example embodiment performs software processing that is the same as or similar to that performed by the server that provides the service. A third reason for the advantageous effect is that according to the communication apparatus and the communication method in accordance with this example embodiment, it is possible to determine that communication data is one that has been transmitted from an application-specific terminal. Further, it is also possible to determine that communication data is one that is transmitted to an application-specific server. A fourth reason for the advantageous effect is that in the communication apparatus and the communication method according to this example embodiment, it is possible to perform, while performing communication, machine learning by using data of that communication as teacher data. A fifth reason for the advantageous effect is that, in the communication apparatus and the communication method according to this example embodiment, after a model for machine learning is generated, information about a variable(s) and a software program(s) is sent so that the terminal or the communication apparatus on the transmitting side can perform lossy compression, and the information about the variable(s) and the software program(s) is sent so that the server or the communication apparatus on the receiving side can perform decompression, restoration, and the like of the lossy-compressed data.

### Modified Example of First Example Embodiment

As a modified example of the first example embodiment, another example of operations performed by the evaluation processing unit 216 according to the first example embodiment will be described. In the modified example, the evaluation processing unit 216 performs a statistical hypothesis verification through the below-described procedure in the evaluation process (S215) shown in FIG. 11.

Firstly, the evaluation processing unit 216 calculates an evaluation value representing a difference between data obtained in the input-data inference (S213) and data obtained in the output-data generation (S214). Examples of the method for calculating an evaluation value include a subtraction, calculation of a correlation coefficient, a summation of exclusive ORs for respective bits, and a summation of the numbers of differences in comparisons on a character-by-character (letter-by-letter) basis or a word-by-word basis. For the method for calculating an evaluation value, only one of these methods may be used or a combination of some of them may be used. The method for calculating an evaluation value may be controlled by using a variable a.

The evaluation processing unit 216 stores the calculated evaluation value (the evaluation data) in a memory, and the stored evaluation value is used in the next machine-learning process. Further, the evaluation value calculated in the evaluation process in the next machine learning process is also stored in the memory. Therefore, every time input data is transmitted/received and the machine learning is repeated, the amount of evaluation value data stored in the memory increases (i.e., evaluation value data is accumulated in the memory).

When the number of the evaluation value data stored in the memory exceeds a predetermined variable b, the evaluation processing unit 216 performs a hypothesis verification. Specifically, the evaluation processing unit 216 determines values and elements necessary for the hypothesis verification, such as the type of the hypothesis verification, the type of a probability distribution, a variance value, a critical region, an acceptance region, and a significance level, according to a predetermined variable c. Then, the evaluation processing unit 216 performs calculation for verifying whether or not the distribution of evaluation values stored in the memory conforms to the aforementioned probability distribution. In other words, the evaluation processing unit 216 determines whether or not a null hypothesis that does not conform to the probability distribution should be rejected.

When the null hypothesis is not rejected (when it does not conform to the probability distribution), the machine-learning process (S207) continues with the model generation process (the machine-learning process) (i.e., is repeated). Further, when the null hypothesis is rejected (when it conforms to the probability distribution), the machine-learning process is finished and the compression method notification (S301) and the inference method notification (S302) are performed.

For example, the number of evaluation value data stored in the memory is controlled by using a variable d. When the number of evaluation value data exceeds the variable d, the evaluation processing unit 216 erases at least one piece of evaluation value data in a chronological order from the oldest one.

Even after the null hypothesis is rejected, the evaluation processing unit 216 continues the statistical hypothesis verification process in a successive manner. Then, when no null hypothesis is rejected any longer, the model generation process is performed again by the machine-learning process (S204 and S207).

### Second Example Embodiment

Next, a second example embodiment will be described. This example embodiment is an example in which a machine-learning server is provided in the base station in the first example embodiment. The rest is similar to that in the first example embodiment.

FIG. 13 shows an example of a configuration of a base station according to this example embodiment. As shown in FIG. 13, in this example, a base station 1001 includes a master station 1002, a slave station 202, a machine-learning server 1004, and a layer-2 switch 1003. The configuration of the slave station 202 is identical to that in the first example embodiment.

The master station 1002 is connected to the core network 103 through the layer-2 switch 1003, and also connected to the machine-learning server 1004 through the layer-2 switch 1003. The machine-learning server 1004 is connected to the core network 103 through the layer-2 switch 1003.

The layer-2 switch 1003 has a switching function of a layer 2. The layer-2 switch 1003 is connected between the core network 103 and the master station 1002 and the machine-learning server 1004 (i.e., between the core network 103 and the master station 1002 and between the core network 103 and the machine-learning server 1004), and performs switching and relaying of communication between each apparatus and the network. Note that the layer-2 switch 1003 is not limited to the layer-2 switch and may be other types of relay apparatuses. For example, the layer-2 switch 1003 may have, among the functions of the master station 201 shown in FIG. 5, the switching unit 304 and performs a switching process of the switching unit 304. The switching process is implemented by a device (an integrated circuit) or software processing. The switching process of the switching unit 304 may be performed by the layer-2 switch 1003 and the machine-learning server 1004.

The machine-learning server 1004 is a learning apparatus that performs a machine-learning process. The machine-learning server 1004 includes, among the processing units (the software processing) of the master station 201 shown in FIG. 6, the machine learning processing unit 210, and may further include a data transmitting/receiving unit 211 and/or a notification unit 217 as required. That is, the machine-learning server 1004 includes the variable control unit 212, the lossy-compression processing unit 213, the model generation processing unit 214, the data inference processing unit 215, and the evaluation processing unit 216. Further, similarly to the first example embodiment, the machine-learning server 1004 performs the machine-learning process (S204) shown in FIG. 11.

In this example, the machine-learning server 1004 acquires input data from the terminal 101, acquires output data from the service providing server 105, transmits inferred data of the input data to the local server 602, and receives inferred data of the output data from the local server 602 through the layer-2 switch 1003. Note that the master station 1002 has the functions of the master station 201 according to the first example embodiment except for the functions of the switching unit 304 and the machine learning processing unit 210.

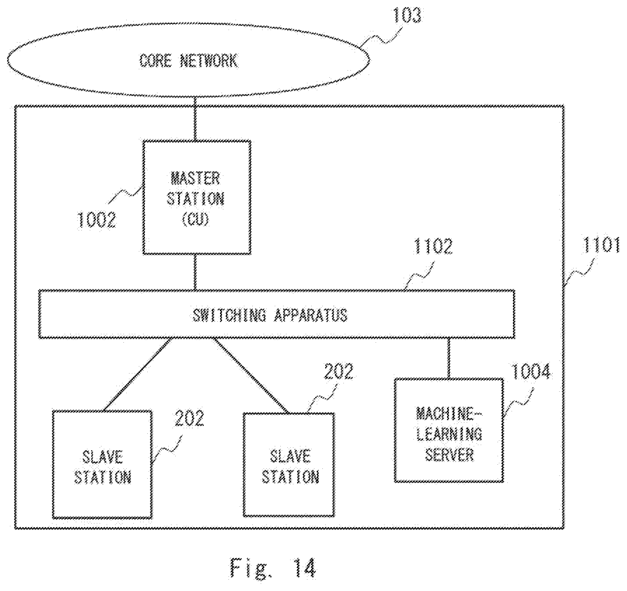

FIG. 14 shows another example of a configuration of a base station according to this example embodiment. As shown in FIG. 14, in this example, the base station 1101 includes a master station 1002, a slave station 202, a machine-learning server 1004, and a switching apparatus 1102. As compared to FIG. 13, the base station 1101 includes the switching apparatus 1102 in place of the layer-2 switch 1003.

The switching apparatus 1102 has an interface and a switching function between the master station 1002 and the slave station 202. The switching apparatus 1102 is connected between the master station 1002 and the slave station 202, and switches (i.e., select) and relays communication of each apparatus. The machine-learning server 1004 is connected to the master station 1002 through the switching apparatus 1102, and is connected to the core network 103 through the master station 1002.

In this example, the machine-learning server 1004 acquires input data from the terminal 101 through the switching apparatus 1102, acquires output data from the service providing server 105 through the switching apparatus 1102 and the master station 1002, transmits inferred data of the input data to the local server 602, and receives inferred data of the output data from the local server 602.

As described above, the machine-learning process in the first example embodiment may be implemented by the machine-learning server disposed in the base station. Even in this case, it is possible to obtain the same advantageous effects as those in the first example embodiment and to reduce the load on the master station of the base station.

### Third Example Embodiment

Next, a third example embodiment will be described. This example embodiment is an example in which the machine-learning server in the second example embodiment is provided in a user-plane apparatus of the core network. The rest is similar to those in the first and second example embodiments.

FIG. 15 shows an example of a configuration of a user-plane apparatus 502 according to this example embodiment. As shown in FIG. 15, similarly to the first example embodiment shown in FIG. 9, the user-plane apparatus 502 includes a plurality of user-plane units 603 and 604, a local area data network 601, and a local server 602, and also includes a machine-learning server 1004 similar to that in the second example embodiment.

The machine-learning server 1004 is connected to the local area data network 601, connected to the local server 602 through the local area data network 601, and connected to the base station 102 through the local area data network 601 and the user-plane unit 603. The number of machine-learning servers 1004 and the number of local servers 602 may be arbitrarily determined.

In this example, the machine-learning server 1004 and the local server 602 constitute one local server 1201. For example, each of the machine-learning server 1004 and the local server 602 may be formed by a virtual server, and the local server 1201 including these virtual servers may be formed by one physical server. Alternatively, for example, software processing of the machine-learning server 1004 and the local server 602 may be implemented by software processing performed by the local server 1201.

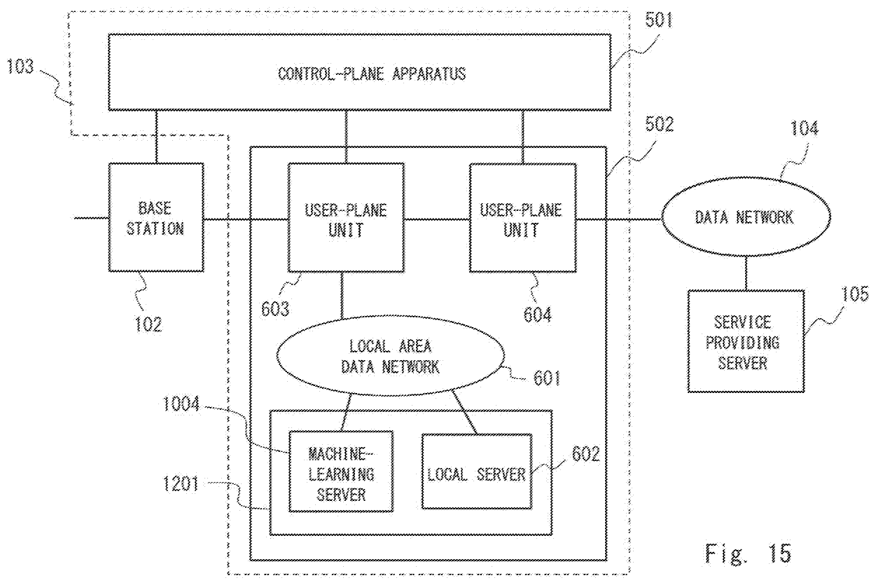

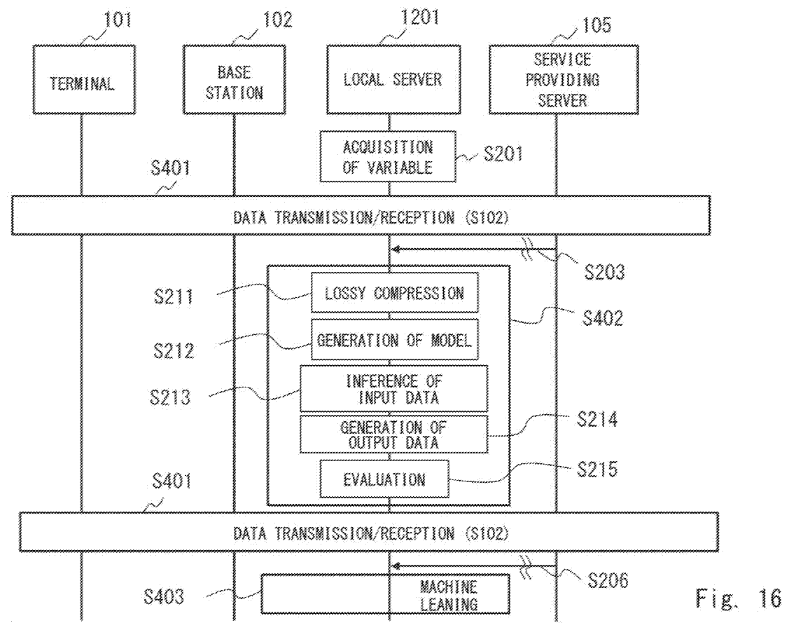

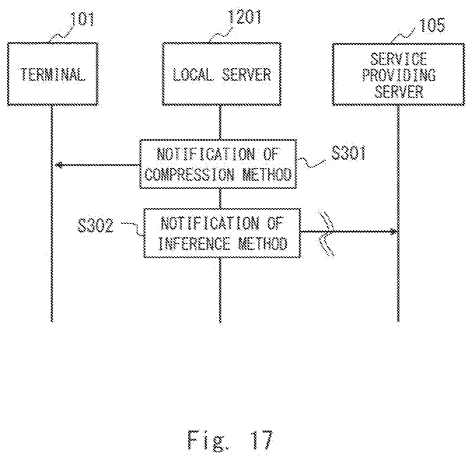

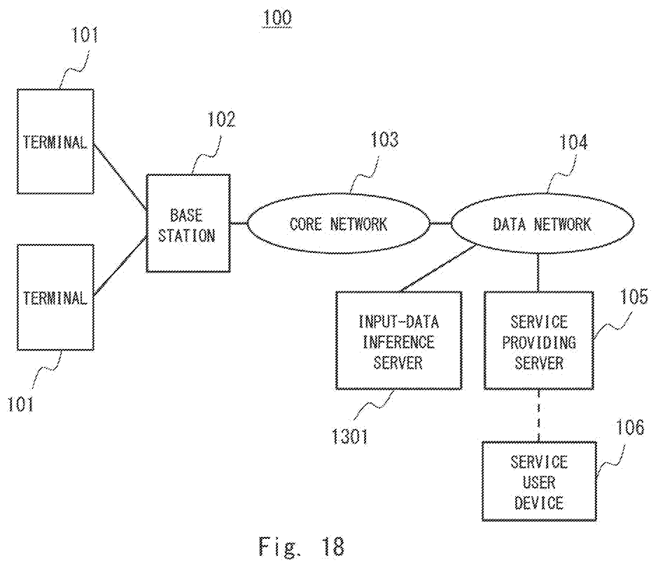

FIGS. 16 and 17 show operations performed by the local server 1201. As shown in FIG. 16, similarly to the first example embodiment shown in FIG. 11, the local server 1201 acquires several variables (S201).

Next, similarly to FIG. 11, data is transmitted and received between the terminal 101 and the service providing server 105 (S401). In the step S401, the local server 1201 acquires input data without interrupting this communication. Specifically, the user-plane unit 603 transmits data received from the base station 102 to both the service providing server 105 and the local server 1201. Further, similarly to FIG. 11, the local server 1201 acquires output data from the service providing server 105 (S203).

Next, the local server 1201 performs a machine-learning process in steps S402 and S403. Similarly to the machine-learning process (S204 and S207) shown in FIG. 11, the machine-learning process (S402 and S403) according to this example embodiment includes a lossy-compression process (S211), a model generation process (S212), an input-data inference process (S213), an output-data generation process (S214), and an evaluation process (S215). Unlike the machine-learning process (S204 and S207) shown in FIG. 11, in the machine-learning process (S402 and S403) according to this example embodiment, each of the processes (S211 to S215) is performed by the local server 1201 alone without cooperation with the base station 102.

After that, as shown in FIG. 17, the local server 1201 notifies the terminal 101 of a method for lossy-compress input data (S301) as in the case of the first example embodiment shown in FIG. 12. Further, similarly to FIG. 12, the local server 1201 notifies the service providing server 105 of a method for inferring input data (S302). After that, similarly to FIG. 12, the terminal 101 lossy-compresses input data, and the service providing server 105 infers the input data.

As described above, the machine-learning server according to the second example embodiment may be provided in the core network. Further, the machine-learning server and the local server may be formed as one server. Even in this case, it is possible to obtain the same advantageous effects as those in the first and second example embodiments, reduce the load on the base station, and efficiently perform the machine-learning process by using one server.

### Fourth Example Embodiment

Next, a fourth example embodiment will be described. This example embodiment is an example in which an input-data inference server is provided separately from the service providing server in the first to third example embodiments. The rest is similar to those in the first to third example embodiments.

FIG. 18 shows an example of a configuration of a communication system 100 according to this example embodiment. As shown in FIG. 18, the communication system 100 includes an input-data inference server 1301 in addition to the configuration of the first example embodiment shown in FIG. 3. The input-data inference server 1301 is connected to the data network 104, and also connected to the core network 103 and the service providing server 105 through the data network 104. The input-data inference server 1301 is an inference apparatus that infers input data from compressed data based on an inference method using learning results (i.e., using a model).

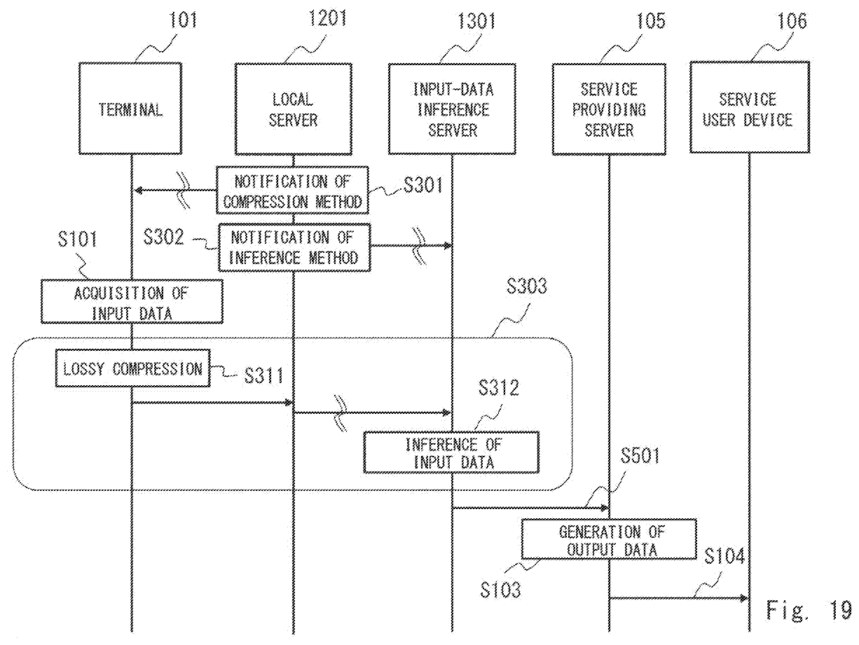

FIG. 19 shows operations performed by the input-data inference server 1301. In this example, similarly to the third example embodiment, the local server 1201 performs machine learning and notifies (i.e., sends information about) a compression method and an inference method according to the learning result. Note that similarly to the first and second embodiments, the base station 102 may perform machine learning and notify (i.e., send information about) a compression method and an inference method according to the learning result.

Similarly to FIG. 17, the local server 1201 notifies the terminal 101 of a method for lossy-compress input data (S301). Further, similarly to FIG. 17, the local server 1201 notifies the input-data inference server 1301 of a method for inferring input data (S302).

Similarly to FIG. 12, the terminal 101 lossy-compresses input data by the compression method notified (i.e., indicated) in the step S301 (S311), and transmits the lossy-compressed data (the input data) to the input-data inference server 1301. Similarly to FIG. 12, the input-data inference server 1301 receives the lossy-compressed data and infers the input data from the received data (i.e., performs decompression, restoration, and the like for the lossy-compressed data) by using the inference method notified (i.e., indicated) in the step S302 (S312). Next, the input-data inference server 1301 transmits the inferred input data to the service providing server 105 (S501). After that, the service providing server 105 generates output data from the inferred input data (S103), and provides the generated output data to the service user device 106 (S104).

As described above, the input-data inference server may be provided separately from the service providing server in the communication system according to the first to third example embodiments. Even in this case, it is possible to obtain the same advantageous effects as those in the first to third example embodiments and to reduce the load on the service providing server.

### Other Example Embodiment

In the above-described example embodiments, the terminal 101 is notified of the compression method in the step S301 in FIGS. 12, 17 and 19, and the terminal 101 lossy-compresses the input data by using this compression method. Then, the service providing server 105 or the input-data inference server 1301 is notified of the inference method in the step S302 in FIGS. 12, 17 and 19, and these servers infer the input data (i.e., performs the decompression, the restoration, and the like).

The methods for the lossy-compression and the input-data inference are not limited to these examples. For example, other transmitting-side apparatuses and receiving-side apparatuses may perform lossy compression and input-data inference in a manner similar to those performed by the terminal 101 and the service providing server 105, or performed by the input-data inference server 1301. That is, the transmitting-side apparatus is notified of the compression method in the step S301, and the transmitting-side apparatus lossy-compresses the input data by using this compression method. Then, the receiving-side apparatus is notified of the inference method in the step S302, and the receiving-side apparatus infers the input data (i.e., performs decompression, restoration, and the like for the lossy-compressed data).

For example, the transmitting-side apparatus has a function of performing lossy compression, and the function of performing lossy compression is implemented by one or both of a device (an integrated circuit) and software processing. The receiving-side apparatus has a function of inferring input data (i.e., performing decompression, restoration, and the like), and this function is implemented by one or both of a device (an integrated circuit) and software processing.

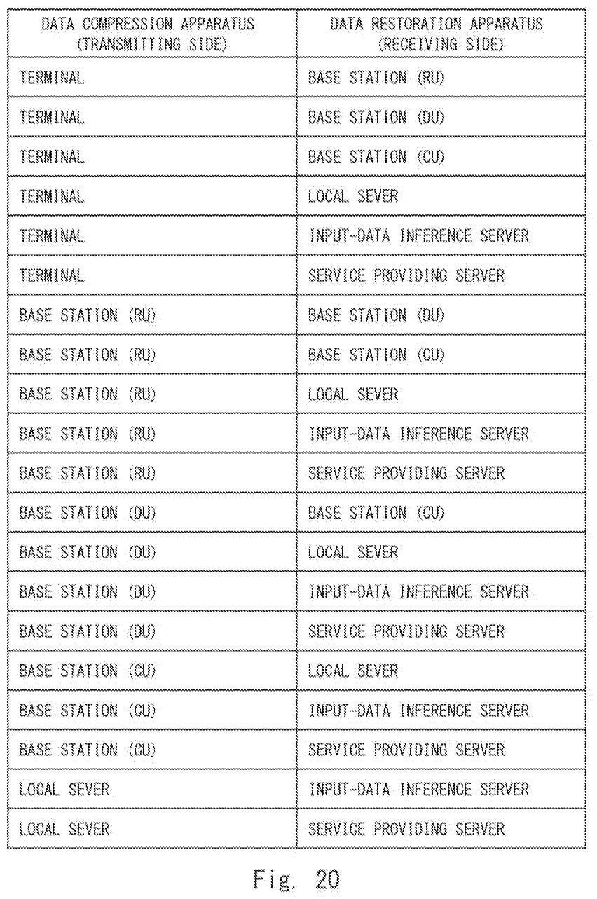

FIG. 20 shows an example of a specific combination of a transmitting-side apparatus (a data compression apparatus) and a receiving-side apparatus (a data restoration apparatus) in the above-described case. For example, the transmitting-side apparatus may be one of a terminal, a remote unit (RU) of a base station, a distributed unit (DU) of the base station, a central unit (CU) of the base station, and a local server. Further, the receiving-side apparatus may be one of a remote unit (RU) of a base station, a distributed unit (DU) of the base station, a central unit (CU) of the base station, a local server, an input-data inference server, and a service providing server. Note that, depending on the configuration of the radio communication network and the apparatus, the transmitting-side apparatus and the receiving-side apparatus are not limited to the examples shown in FIG. 20, and may be an arbitrary combination of one of the transmitting-side apparatuses and one of the receiving-side apparatuses.

Further, as another example, some of the software processing processes in the above-described example embodiments may be performed by the control-plane apparatus 501 of the core network 103. For example, the control-plane apparatus 501 controls the base station 102 and/or the user-plane apparatus 502 by software processing. The control-plane apparatus 501 may exchange (receive/output) several variables, software, input data, output data, and inferred data in the above-described example embodiments with (from/to) the base station 102 and/or the user-plane apparatus 502.

As explained above with reference to example embodiment, according to the present disclosure, it is possible to provide a learning apparatus, a communication system, a learning method, and a learning program capable of coping with arbitrary communication data.

Note that the present disclosure is not limited to the above-described example embodiments, and they may be modified as appropriate without departing from the spirit of the present disclosure. For example, in the above-described example embodiments, examples in which communication data is lossy-compressed (including being thinning out) have been described. However, the present disclosure may be applied to other compression methods and conversion methods (a format conversion, a size conversion, and the like).

Each of the configurations in the above-described example embodiments may be constructed by software, hardware, or both of them. Further, each of the configurations may be formed by one hardware device or one software program, or a plurality of hardware devices or a plurality of software programs. The function (the process) of each apparatus may be implemented by a computer including a CPU (Central Processing Unit), a memory, and the like. For example, a program for causing the computer to perform a method according to an example embodiment may be stored in a storage device, and each function may be implemented by having the CPU execute the program stored in the storage device.

The program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g., magneto-optical disks), CD-ROM (Read Only Memory), CD-R, CD-R/W, and semiconductor memories (such as mask ROM, PROM (Programmable ROM), EPROM (Erasable PROM), flash ROM, RAM (Random Access Memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g., electric wires, and optical fibers) or a wireless communication line.

The whole or part of the example embodiments disclosed above can be described as, but not limited to, the following supplementary notes.

(Supplementary Note 1)

A learning apparatus comprising:

an acquisition unit configured to acquire communication data transmitted to a network; and

a learning unit configured to perform machine learning by using the acquired communication data as teacher data.

(Supplementary Note 2)

The learning apparatus described in Supplementary note 1, wherein the learning unit machine-learns communication data before it is transmitted to the network and the communication data after it is transmitted to the network by using the acquired communication data as the teacher data.

(Supplementary Note 3)

The learning apparatus described in Supplementary note 2, wherein

the network includes a first communication apparatus and a second communication apparatus,

the acquisition unit acquires input data transmitted from the first communication apparatus to the second communication apparatus, and acquires output data that the second communication apparatus outputs based on the input data, and

the learning unit performs machine learning by using the acquired input data and the acquired output data as the teacher data.

(Supplementary Note 4)

The learning apparatus described in Supplementary note 3, wherein

the learning unit comprises:

a conversion unit configured to convert the acquired input data by a predetermined conversion method;

a generation unit configured to generates a learning model for inferring input data that has not been converted from converted input data;

an inference unit configured to infer the input data that has not been converted from the converted input data by using the learning model; and

an evaluation unit configured to evaluate the learning model by comparing output data based on the inferred input data with the acquired output data.

(Supplementary Note 5)

The learning apparatus described in Supplementary note 4, further comprising an output-data generation unit configured to generate output data based on the inferred input data by an output-data generation method performed by the second communication apparatus.

(Supplementary Note 6)

The learning apparatus described in Supplementary note 4 or 5, further comprising a setting unit configured to set the conversion method, wherein

the setting unit adjusts the conversion method based on the evaluation result.

(Supplementary Note 7)

The learning apparatus described in Supplementary note 6, further comprising a notification unit configured to notify the first communication apparatus of information about the adjusted conversion method.

(Supplementary Note 8)

The learning apparatus described in Supplementary note 6 or 7, wherein the information about the conversion method includes a parameter for the conversion method or information about a program for performing the conversion method.

(Supplementary Note 9)

The learning apparatus described in any one of Supplementary notes 4 to 8, wherein the predetermined conversion method is a lossy-compression method.

(Supplementary Note 10)

The learning apparatus described in Supplementary note 4 or 5, further comprising a setting unit configured to set an inference method for generating the learning model, wherein

the setting unit adjusts the inference method based on the evaluation result.

(Supplementary Note 11)

The learning apparatus described in Supplementary note 10, further comprising a notification unit configured to notify the second communication apparatus of information about the adjusted inference method.

(Supplementary Note 12)

The learning apparatus described in Supplementary note 10 or 11, wherein the information about the inference method includes a parameter for the inference method, information about a program for performing the inference method, or information about the learning model.

(Supplementary Note 13)

A communication system comprising a first communication apparatus, a second communication apparatus, and a learning apparatus, wherein

the learning apparatus comprises:

an acquisition unit configured to acquire communication data transmitted to a network including the first and second communication apparatuses; and

a learning unit configured to perform machine learning by using the acquired communication data as teacher data.

(Supplementary Note 14)

The communication system described in Supplementary note 13, further comprising a relay apparatus configured to relay communication between the first and second communication apparatuses, wherein

the relay apparatus comprises the learning apparatus.

(Supplementary Note 15)

The communication system described in Supplementary note 13 or 14, wherein the learning unit machine-learns communication data before it is transmitted to the network and the communication data after it is transmitted to the network by using the acquired communication data as the teacher data.

(Supplementary Note 16)

The communication system described in Supplementary note 15, wherein

the acquisition unit acquires input data transmitted from the first communication apparatus to the second communication apparatus, and acquires output data that the second communication apparatus outputs based on the input data, and

the learning unit performs machine learning by using the acquired input data and the acquired output data as the teacher data.

(Supplementary Note 17)

The communication system described in Supplementary note 16, further comprising an output-data generation apparatus configured to perform an output-data generation process of the second communication apparatus, wherein

the learning apparatus performs machine learning by using output data generated by the output-data generation apparatus.

(Supplementary Note 18)

The communication system described in Supplementary note 17, further comprising a server comprising the learning apparatus and the output-data generation apparatus.

(Supplementary Note 19)

The communication system described in any one of Supplementary notes 16 to 18, wherein the first communication apparatus converts the input data based on a result of the machine learning by a predetermined conversion method.

(Supplementary Note 20)

The communication system described in Supplementary note 19, wherein the second communication apparatus infers input data that has not been converted from converted input data based on the result of the machine learning.

(Supplementary Note 21)

The communication system described in Supplementary note 19, further comprising an inference apparatus configured to infer the input data that has not been converted from the converted input data based on the result of the machine learning.

(Supplementary Note 22)

A learning method comprising:

acquiring communication data transmitted to a network; and

performing machine learning by using the acquired communication data as teacher data.

(Supplementary Note 23)

The learning method described in Supplementary note 22, wherein in the machine learning, communication data before it is transmitted to the network and the communication data after it is transmitted to the network are machine-learned by using the acquired communication data as the teacher data.

(Supplementary Note 24)

A learning program for causing a computer to:

acquire communication data transmitted to a network; and

perform machine learning by using the acquired communication data as teacher data.

(Supplementary Note 25)

The learning program described in Supplementary note 24, wherein in the machine learning, communication data before it is transmitted to the network and the communication data after it is transmitted to the network are machine-learned by using the acquired communication data as the teacher data.

The first to fourth embodiments can be combined as desirable by one of ordinary skill in the art.

While the disclosure has been particularly shown and described with reference to embodiments thereof, the disclosure is not limited to these embodiments. It will be understood by those of ordinary skill in the art that various changes in form and details may be made therein without departing from the spirit and scope of the present disclosure as defined by the claims.

What is claimed is:

1. A learning apparatus comprising:
an acquisition unit configured to acquire communication data transmitted to a network; and
a learning unit configured to perform machine learning by using the acquired communication data as teacher data.

2. The learning apparatus according to claim 1, wherein the learning unit machine-learns communication data before it is transmitted to the network and the communication data after it is transmitted to the network by using the acquired communication data as the teacher data.

3. The learning apparatus according to claim 2, wherein
the network includes a first communication apparatus and a second communication apparatus,
the acquisition unit acquires input data transmitted from the first communication apparatus to the second communication apparatus, and acquires output data that the second communication apparatus outputs based on the input data, and
the learning unit performs machine learning by using the acquired input data and the acquired output data as the teacher data.

4. The learning apparatus according to claim 3, wherein
the learning unit comprises:
a conversion unit configured to convert the acquired input data by a predetermined conversion method;
a generation unit configured to generates a learning model for inferring input data that has not been converted from converted input data;
an inference unit configured to infer the input data that has not been converted from the converted input data by using the learning model; and
an evaluation unit configured to evaluate the learning model by comparing output data based on the inferred input data with the acquired output data.

5. The learning apparatus according to claim 4, further comprising an output-data generation unit configured to generate output data based on the inferred input data by an output-data generation method performed by the second communication apparatus.

6. The learning apparatus according to claim 4, further comprising:
a setting unit configured to set the conversion method and adjust the conversion method based on the evaluation result; and
a notification unit configured to notify the first communication apparatus of information about the adjusted conversion method.

7. The learning apparatus according to claim 6, wherein the information about the conversion method includes a parameter for the conversion method or information about a program for performing the conversion method.

8. The learning apparatus according to claim 4, wherein the predetermined conversion method is a lossy-compression method.

9. The learning apparatus according to claim 4, further comprising:
a setting unit configured to set an inference method for generating the learning model and adjust the inference method based on the evaluation result; and
a notification unit configured to notify the second communication apparatus of information about the adjusted inference method.

10. The learning apparatus according to claim 9, wherein the information about the inference method includes a parameter for the inference method, information about a program for performing the inference method, or information about the learning model.

11. A communication system comprising a first communication apparatus, a second communication apparatus, and a learning apparatus, wherein
the learning apparatus comprises:
an acquisition unit configured to acquire communication data transmitted to a network including the first and second communication apparatuses; and
a learning unit configured to perform machine learning by using the acquired communication data as teacher data.

12. The communication system according to claim 11, further comprising a relay apparatus configured to relay communication between the first and second communication apparatuses, wherein
the relay apparatus comprises the learning apparatus.

13. The communication system according to claim 11, wherein the learning unit machine-learns communication data before it is transmitted to the network and the communication data after it is transmitted to the network by using the acquired communication data as the teacher data.

14. The communication system according to claim 13, wherein
the acquisition unit acquires input data transmitted from the first communication apparatus to the second communication apparatus, and acquires output data that the second communication apparatus outputs based on the input data, and
the learning unit performs machine learning by using the acquired input data and the acquired output data as the teacher data.

15. The communication system according to claim 14, further comprising an output-data generation apparatus configured to perform an output-data generation process of the second communication apparatus, wherein
the learning apparatus performs machine learning by using output data generated by the output-data generation apparatus.

16. The communication system according to claim 15, further comprising a server comprising the learning apparatus and the output-data generation apparatus.

17. The communication system according to claim 14, wherein the first communication apparatus converts the input data based on a result of the machine learning by a predetermined conversion method.

18. The communication system according to claim 17, wherein the second communication apparatus infers input data that has not been converted from converted input data based on the result of the machine learning.

19. The communication system according to claim 17, further comprising an inference apparatus configured to infer the input data that has not been converted from the converted input data based on the result of the machine learning.

20. A learning method comprising:
acquiring communication data transmitted to a network; and
performing machine learning by using the acquired communication data as teacher data.
